(19) United States
(12) Patent Application Publication
(10) Pub. No.: US 2025/0372486 A1
(43) Pub. Date: Dec. 4, 2025

(54) SEMICONDUCTOR DEVICE

(71) Applicant: ROHM CO., LTD., Kyoto (JP)

(72) Inventor: Yusuke HARADA, Kyoto (JP)

(21) Appl. No.: 19/214,429

(22) Filed: May 21, 2025

(30) Foreign Application Priority Data
May 28, 2024 (JP) 2024-085989

(51) Int. Cl. H01L 23/495; H01L 23/00; H01L 23/31

(52) U.S. Cl. CPC H01L 23/49548; H01L 23/3107; H01L 23/49517; H01L 24/16; H01L 24/32; H01L 24/48; H01L 24/73; H01L 2224/16245; H01L 2224/32245; H01L 2224/48245; H01L 2224/73265

(57) ABSTRACT

A semiconductor device includes: a semiconductor element; a sealing resin configured to cover the semiconductor element, the sealing resin including a resin main surface and a resin back surface, a first resin side surface, and a second resin side surface; a first lead including a first back surface, a first end surface, and a second end surface; a second lead electrically connected to the semiconductor element and including a second back surface exposed from the resin back surface and a third end surface exposed from the first resin side surface; a third lead provided between the first lead and the second lead in the first direction and including a third back surface exposed from the resin back surface and a fourth end surface exposed from the first resin side surface; and a first connector configured to connect the first lead and the third lead.

### CROSS-REFERENCE TO RELATED APPLICATION

This application is based upon and claims the benefit of priority from Japanese Patent Application No. 2024-085989, filed on May 28, 2024, the entire contents of which are incorporated herein by reference.

### TECHNICAL FIELD

The present disclosure relates to a semiconductor device.

### BACKGROUND

In the related art, an example of a semiconductor device is known. The semiconductor device known in the art includes a semiconductor element, a plurality of leads, and a sealing resin. Each of the leads has a mounting surface exposed from a back surface of the sealing resin and an end surface exposed from a side surface of the sealing resin.

### BRIEF DESCRIPTION OF DRAWINGS

The accompanying drawings, which are incorporated in and constitute a part of the specification, illustrate embodiments of the present disclosure.

FIG. 1 is a plan view showing a semiconductor device according to embodiments of the present disclosure.

FIG. 2 is a partial plan view showing the semiconductor device according to the embodiments of the present disclosure.

FIG. 3 is a bottom view showing the semiconductor device according to the embodiments of the present disclosure.

FIG. 4 is a front view showing the semiconductor device according to the embodiments of the present disclosure.

FIG. 5 is a side view showing the semiconductor device according to the embodiments of the present disclosure.

FIG. 6 is a cross-sectional view taken along line VI-VI in FIG. 2.

FIG. 7 is a cross-sectional view taken along line VII-VII in FIG. 2.

FIG. 8 is a cross-sectional view taken along line VIII-VIII in FIG. 2.

FIG. 9 is a cross-sectional view taken along line IX-IX in FIG. 2.

FIG. 10 is a cross-sectional view taken along line X-X in FIG. 2.

FIG. 11 is a cross-sectional view taken along line XI-XI in FIG. 2.

FIG. 12 is a cross-sectional view taken along line XII-XII in FIG. 2.

FIG. 13 is a cross-sectional view taken along line XIII-XIII in FIG. 2.

FIG. 14 is a cross-sectional view taken along line XIV-XIV in FIG. 2.

FIG. 15 is a cross-sectional view taken along line XV-XV in FIG. 2.

FIG. 16 is a partially enlarged plan view showing the semiconductor device according to the embodiments of the present disclosure.

FIG. 17 is a partially enlarged cross-sectional view taken along line XVII-XVII in FIG. 16.

FIG. 18 is a partially enlarged cross-sectional view showing a first modification of the semiconductor device according to the embodiments of the present disclosure.

FIG. 19 is a partially enlarged cross-sectional view showing a second modification of the semiconductor device according to the embodiments of the present disclosure.

FIG. 20 is a partially enlarged plan view showing a third modification of the semiconductor device according to the embodiments of the present disclosure.

FIG. 21 is a partially enlarged front view showing a third modification of the semiconductor device according to the embodiments of the present disclosure.

FIG. 22 is a partially enlarged plan view showing a semiconductor device according to embodiments of the present disclosure.

FIG. 23 is a partially enlarged cross-sectional view taken along line XXIII-XXIII in FIG. 22.

FIG. 24 is a partially enlarged plan view showing a semiconductor device according to embodiments of the present disclosure.

FIG. 25 is a partially enlarged cross-sectional view taken along line XXV-XXV in FIG. 24.

FIG. 26 is a partially enlarged plan view showing a semiconductor device according to embodiments of the present disclosure.

FIG. 27 is a cross-sectional view showing a semiconductor device according to embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, the embodiments of the present disclosure will be described in detail with reference to the drawings.

The terms “first,” “second,” “third,” and the like in the present disclosure are used merely for identification purposes and are not intended to impose any ordering on their objects.

In the present disclosure, “a certain object A is formed in a certain object B” and “a certain object A is formed on a certain object B” include “a certain object A is formed directly in a certain object B” and “a certain object A is formed in a certain object B with another object interposed between the certain object A and the certain object B,” unless otherwise specified. Similarly, “a certain object A is disposed in a certain object B” and “a certain object A is disposed on a certain object B” include “a certain object A is disposed directly in a certain object B” and “a certain object A is disposed on a certain object B with another object interposed between the certain object A and the certain object B,” unless otherwise specified. Similarly, “a certain object A is located on a certain object B” includes “a certain object A is located on a certain object B in contact with the certain object B” and “a certain object A is located on a certain object B with another object interposed between the certain object A and the certain object B.” Further, “a certain object A overlaps with a certain object B when viewed in a certain direction” includes “a certain object A overlaps with the entire certain object B” and “a certain object A overlaps with a part of the certain object B,” unless otherwise specified. Moreover, in the present disclosure, “a certain surface A faces (one side or the other side of) a direction B” is not limited to a case where the angle of the certain surface A with respect to the direction B is 90°, but also includes a case where the certain surface A is inclined with respect to the direction B.

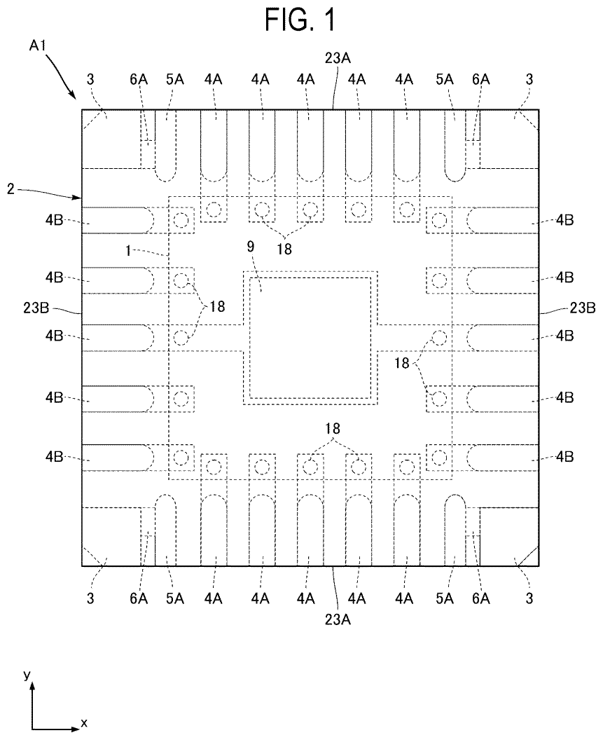

FIGS. 1 to 17 show a semiconductor device according to embodiments of the present disclosure. The semiconductor device A1 of the embodiments includes a semiconductor element 1, a sealing resin 2, one or more first leads 3, one or more second leads 4A, one or more third leads 5A, and one or more first connectors 6A. The semiconductor device A1 may further include one or more fourth leads 4B and an island lead 9. The specific configuration of the semiconductor device A1 is not limited in any way, and may be, for example, a QFN (Quad Flat No Leaded Package) type semiconductor device.

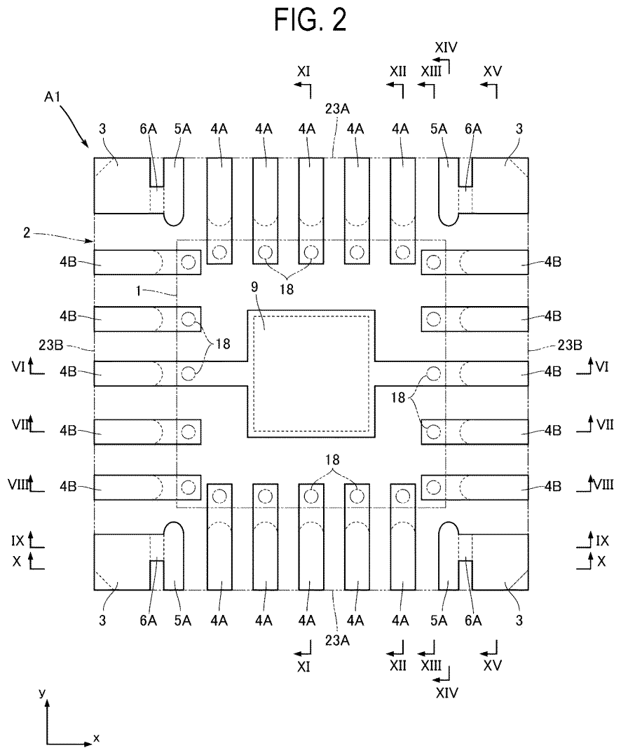

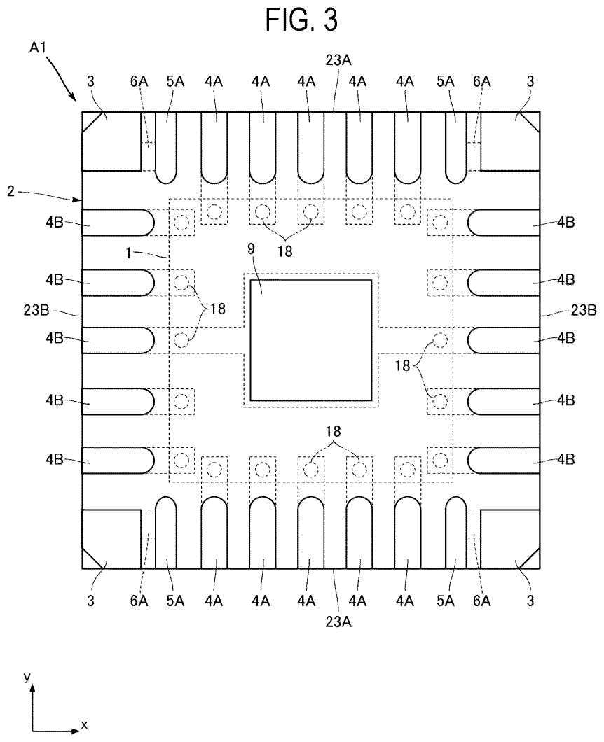

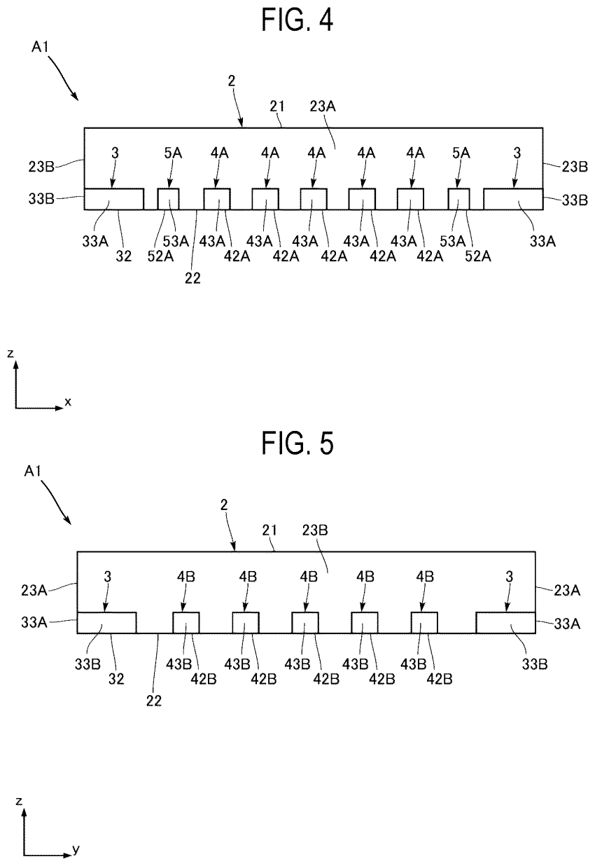

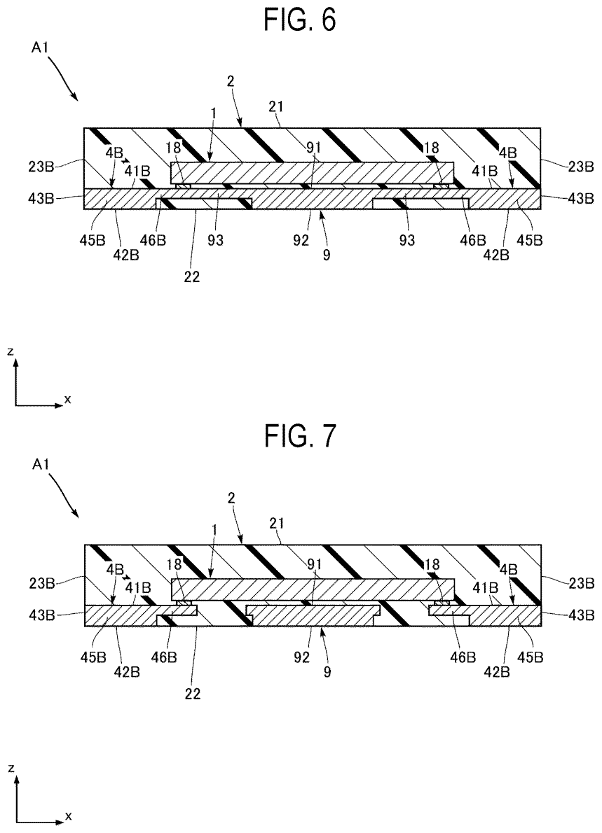

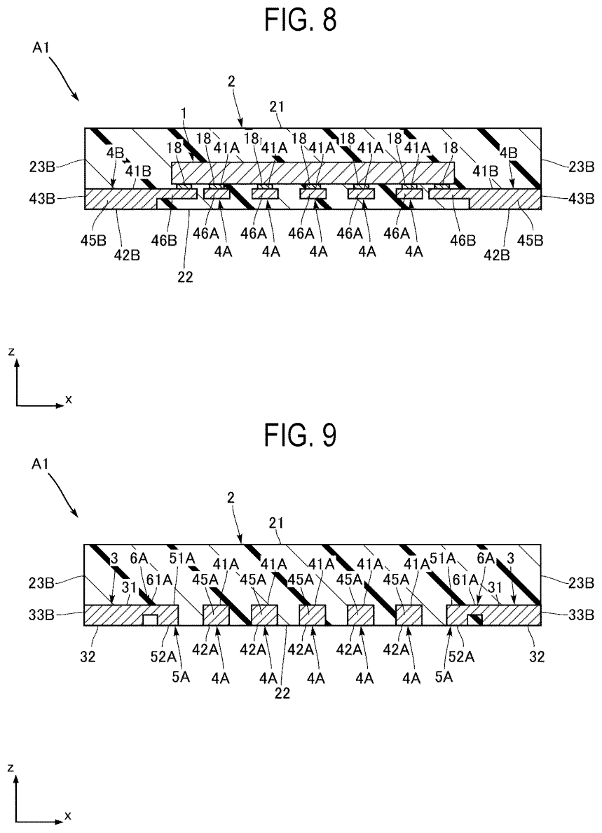

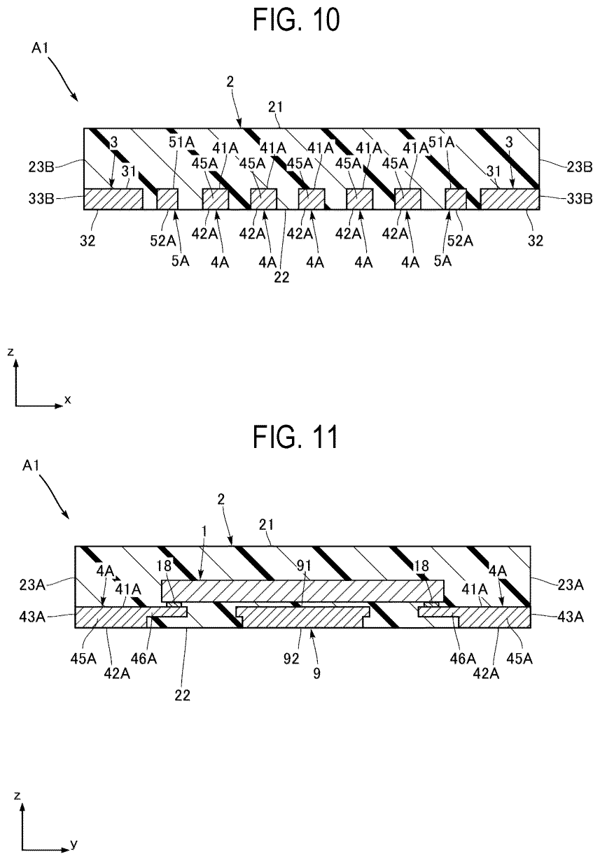

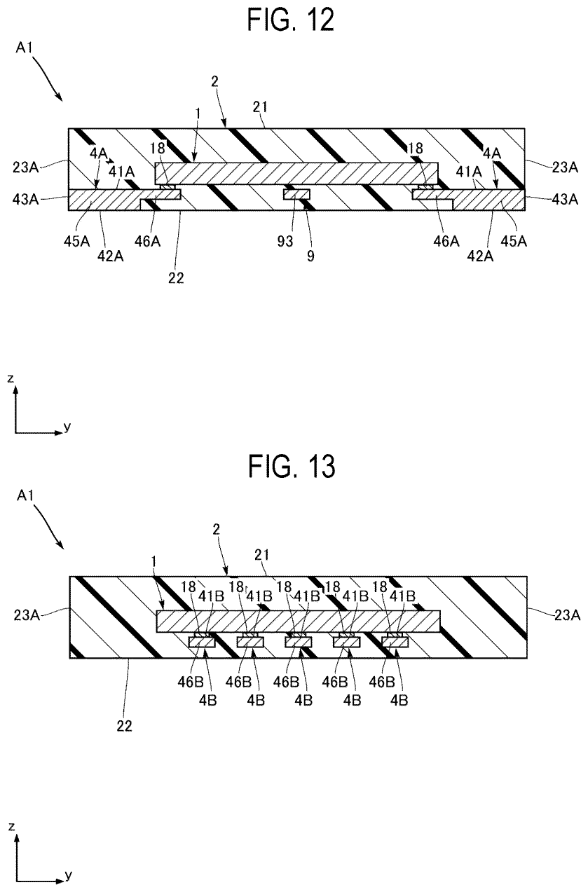

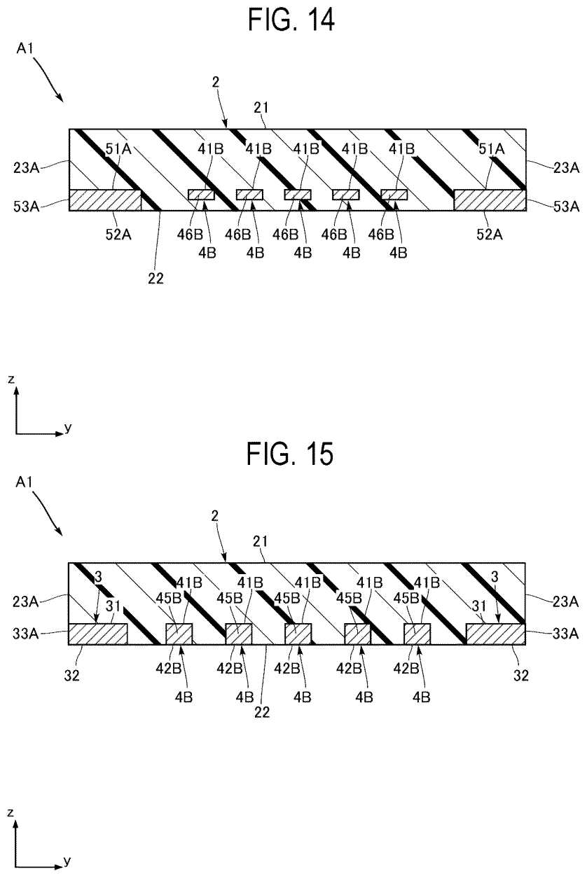

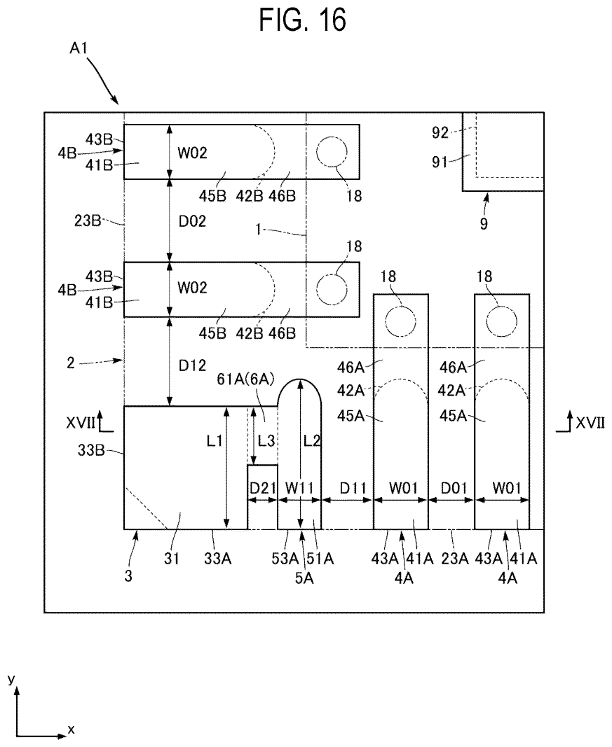

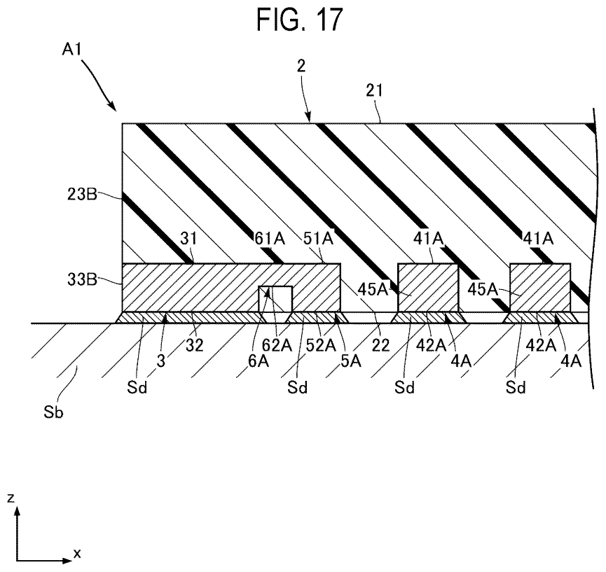

FIG. 1 is a plan view showing a semiconductor device A1. FIG. 2 is a partial plan view showing the semiconductor device A1. FIG. 3 is a bottom view showing the semiconductor device A1. FIG. 4 is a front view showing the semiconductor device A1. FIG. 5 is a side view showing the semiconductor device A1. FIG. 6 is a cross-sectional view taken along line VI-VI in FIG. 2. FIG. 7 is a cross-sectional view taken along line VII-VII in FIG. 2. FIG. 8 is a cross-sectional view taken along line VIII-VIII in FIG. 2. FIG. 9 is a cross-sectional view taken along line IX-IX in FIG. 2. FIG. 10 is a cross-sectional view taken along line X-X in FIG. 2. FIG. 11 is a cross-sectional view taken along line XI-XI in FIG. 2. FIG. 12 is a cross-sectional view taken along line XII-XII in FIG. 2. FIG. 13 is a cross-sectional view taken along line XIII-XIII in FIG. 2. FIG. 14 is a cross-sectional view taken along line XIV-XIV in FIG. 2. FIG. 15 is a cross-sectional view taken along line XV-XV in FIG. 2. FIG. 16 is a partially enlarged plan view showing the semiconductor device A1. FIG. 17 is a partially enlarged cross-sectional view taken along line XVII-XVII in FIG. 16. In FIGS. 2 and 16, for the ease of understanding, the sealing resin 2 is indicated by an imaginary line (two-dot chain line).

In these figures, the thickness direction in the present disclosure is defined as a thickness direction z. A direction perpendicular to the thickness direction z is defined as a first direction x. A direction perpendicular to the thickness direction z and the first direction x is defined as a second direction y.

The semiconductor element 1 performs the main electrical function of the semiconductor device A1 when the semiconductor device A1 is mounted on a circuit board or the like to form a part of an electrical circuit. The specific configuration of the semiconductor element 1 is not limited in any way, and may include an LSI (Large Scale Integration), an IC (Integrated Circuit), etc. When viewed in the thickness direction z, the semiconductor element 1 of the embodiments has a rectangular shape with two sides extending along the first direction x and two sides extending along the second direction y.

There is no limitation on the mounting form of the semiconductor element 1. In the embodiments, the semiconductor element 1 may be mounted on one or more second leads 4A and one or more fourth leads 4B by so-called flip-chip mounting.

The sealing resin 2 covers the semiconductor element 1, the one or more first leads 3, the one or more second leads 4A, parts of the one or more third leads 5A and the one or more first connectors 6A, and parts of the one or more fourth leads 4B and the one or more island leads 9. The specific configuration of the sealing resin 2 is not limited, and the constituent material may include, for example, an epoxy resin. The sealing resin 2 of the embodiments may have a resin main surface 21, a resin back surface 22, two first resin side surfaces 23A, and two second resin side surfaces 23B.

The resin main surface 21 is a surface facing one side in the thickness direction z, and is a flat rectangular surface in the illustrated example. The resin back surface 22 is a surface facing the other side in the thickness direction z, and is a flat rectangular surface in the illustrated example. The two first resin side surfaces 23A are surfaces extending along the first direction x and the thickness direction z. The two second resin side surfaces 23B are surfaces extending along the second direction y and the thickness direction z.

The one or more first leads 3, the one or more second leads 4A, the one or more third leads 5A, the one or more first connectors 6A, the one or more fourth leads 4B, and the island lead 9 perform functions such as supporting the semiconductor element 1, forming a conductive path leading to the semiconductor element 1, and mounting the semiconductor device A1 on a circuit board. The one or more first leads 3, the one or more second leads 4A, the one or more third leads 5A, the one or more first connectors 6A, the one or more fourth leads 4B, and the island lead 9 may contain, for example, Cu (copper), Ni (nickel), Fe (iron), and alloys thereof, as a constituent material thereof. The one or more first leads 3, the one or more second leads 4A, the one or more third leads 5A, the one or more first connectors 6A, the one or more fourth leads 4B, and the island lead 9 may be provided with a metal layer (not shown) formed by plating or the like at appropriate positions.

There is no limitation on the number of the one or more first leads 3. As shown in FIGS. 1 to 3, in the embodiments, the number of the one or more first leads 3 is plural, and is four in the illustrated example. As shown in FIGS. 4, 5, 9, 10, and 15 to 17, the first lead 3 may have a first main surface 31, a first back surface 32, a first end surface 33A, and a second end surface 33B.

The first main surface 31 faces the same side as the resin main surface 21 in the thickness direction z. The first main surface 31 may be covered with the sealing resin 2. The first back surface 32 faces the same other side as the resin back surface 22 in the thickness direction z. The first back surface 32 is exposed from the resin back surface 22. The first back surface 32 may be flush with the resin back surface 22. The first back surface 32 is used as a mounting surface when mounting the semiconductor device A1 on a circuit board.

The first end surface 33A is a surface extending along the thickness direction z and the first direction x. The first end surface 33A may be connected to the first main surface 31 and the first back surface 32. The first end surface 33A is exposed from the first resin side surface 23A. The first end surface 33A may be flush with the first resin side surface 23A.

The second end surface 33B is a surface extending along the thickness direction z and the second direction y. The second end surface 33B may be connected to the first main surface 31 and the first back surface 32. The second end surface 33B may be connected to the first end surface 33A. The second end surface 33B is exposed from the second resin side surface 23B.

The number of the one or more second leads 4A is not limited in any way. As shown in FIGS. 1 to 3, in the embodiments, the number of the one or more second leads 4A is plural, and in the illustrated example, five second leads 4A are arranged on each side extending in the second direction y. The five second leads 4A are provided between two first leads 3 in the first direction x. As shown in FIGS. 4, 8 to 12, 16, and 17, the second lead 4A may have a second main surface 41A, a second back surface 42A, a third end surface 43A, a thick portion 45A, and a thin portion 46A.

The second main surface 41A faces the same side as the resin main surface 21 in the thickness direction z. The second main surface 41A may be covered with the sealing resin 2. The second back surface 42A faces the same other side as the resin back surface 22 in the thickness direction z. The second back surface 42A is exposed from the resin back surface 22. The second back surface 42A may be flush with the resin back surface 22. The second back surface 42A is used as a mounting surface when mounting the semiconductor device A1 on a circuit board.

The third end surface 43A is a surface extending along the thickness direction z and the first direction x. The third end surface 43A may be connected to the second main surface 41A and the second back surface 42A. The third end surface 43A is exposed from the first resin side surface 23A. The third end surface 43A may be flush with the first resin side surface 23A.

The thick portion 45A is a portion that includes at least a portion of the second main surface 41 A and at least a portion of the second back surface 42 A. In the embodiments, the thick portion 45A is located on the outer side of the second lead 4A in the second direction y.

The thin portion 46A is a portion that includes at least a portion of the second main surface 41A, but does not include the second back surface 42A. The thin portion 46A is covered with the sealing resin 2 from the other side in the thickness direction z. In the embodiments, the thin portion 46A extends inward in the second direction y from the thick portion 45A.

The semiconductor element 1 may be conductively bonded to a portion of the second main surface 41A included in the thick portion 45A via a conductive bonding material 18. The conductive bonding material 18 may be, for example, solder.

The number of the one or more third leads 5A is not limited in any way. As shown in FIGS. 1 to 3, in the embodiments, the number of the one or more third leads 5A is plural, and is four in the illustrated example. The third lead 5A is provided between the first lead 3 and the second lead 4A in the first direction x. As shown in FIGS. 4, 9, 10, 16, and 17, the third lead 5A may have a third main surface 51A, a third back surface 52A, and a fourth end surface 53A.

The third main surface 51A faces the same side as the resin main surface 21 in the thickness direction z. The third main surface 51A may be covered with the sealing resin 2. The third back surface 52A faces the same other side as the resin back surface 22 in the thickness direction z. The third back surface 52A is exposed from the resin back surface 22. The third back surface 52A may be flush with the resin back surface 22. The third back surface 52A is used as a mounting surface when mounting the semiconductor device A1 on a circuit board.

The fourth end surface 53A is a surface extending along the thickness direction z and the first direction x. The fourth end surface 53A may be connected to the third main surface 51A and the third back surface 52A. The fourth end surface 53A is exposed from the first resin side surface 23A. The fourth end surface 53A may be flush with the first resin side surface 23A.

The number of the one or more first connectors 6A is not limited in any way. As shown in FIGS. 1 to 3, in the embodiments, the number of the one or more first connectors 6A is plural, and is four in the illustrated example. The first connector 6A is provided between the first lead 3 and the third lead 5A in the first direction x and connect the first lead 3 and the third lead 5A. As shown in FIGS. 9, 16, and 17, the first connector 6A may have a fourth main surface 61A and a fourth back surface 62A.

The fourth main surface 61A faces the same side as the resin main surface 21 in the thickness direction z. The fourth main surface 61A may be covered with the sealing resin 2.

The fourth back surface 62A faces the same side as the resin back surface 22 in the thickness direction z. The fourth back surface 62A may be located between the fourth main surface 61A and the resin back surface 22 in the thickness direction z, and may be covered with the sealing resin 2.

In the illustrated example, the first connector 6A may be spaced apart in the second direction y from the first resin side surface 23A. The first connector 6A may be covered with the sealing resin 2 from the outside in the second direction y.

The first lead 3, the third lead 5A and the first connector 6A may be separate from the semiconductor element 1 and may be insulated from the semiconductor element 1.

As shown in FIG. 16, a size W11 of the third lead 5A in the first direction x may be smaller than a size W01 of the second lead 4A in the first direction x. A distance D11 between the second lead 4A and the third lead 5A in the first direction x may be the same as a distance D01 between the adjacent second leads 4A in the first direction x. A distance D21 between the first lead 3 and the third lead 5A in the first direction x may be smaller than the distance D11. The specific values of the size W01, the size W11, the distance D01, the distance D11, and the distance D21 are not limited in any way. As an example of each value, the size W01 may be 0.15 mm or more and 0.3 mm or less. The size W11 may be 0.1 mm or more and 0.3 mm or less. The distance D01 may be 0.15 mm or more and 0.3 mm or less. The distance D11 may be 0.15 mm or more and 0.6 mm or less. The distance D21 may be 0.15 mm or more and 0.6 mm or less.

A size L3 of the first connector 6A in the second direction y may be smaller than a size L2 of the third lead 5A in the second direction y. The size L3 may be smaller than a size L1 of the first lead 3 in the second direction y. The size L2 may be larger than the size L1. The specific values of the sizes L1, L2, and L3 are not limited in any way. As an example of each value, the size L1 may be 0.2 mm or more and 0.4 mm or less. The size L2 may be 0.21 mm or more and 0.41 mm or less. The size L3 may be 0.1 mm or more and 0.3 mm or less.

The positional relationship in the thickness direction z of the first main surface 31, the second main surface 41A, the third main surface 51A, and the fourth main surface 61A is not limited in any way. In the illustrated example, the first main surface 31, the second main surface 41A, the third main surface 51A, and the fourth main surface 61A may be located at the same position in the thickness direction z.

The number of the one or more fourth leads 4B is not limited in any way. As shown in FIGS. 1 to 3, in the embodiments, the number of the one or more fourth leads 4B is plural, and in the illustrated example, five fourth leads 4B are arranged on each side extending in the first direction x. The five fourth leads 4B are provided between two first leads 3 in the second direction y. As shown in FIGS. 5 to 8 and 13 to 16, the fourth lead 4B may have a fifth main surface 41B, a fifth back surface 42B, a fifth end surface 43B, a thick portion 45B, and a thin portion 46B.

The fifth main surface 41B faces the same side as the resin main surface 21 in the thickness direction z. The fifth main surface 41B may be covered with the sealing resin 2. The fifth back surface 42B faces the same other side as the resin back surface 22 in the thickness direction z. The fifth back surface 42B is exposed from the resin back surface 22. The fifth back surface 42B may be flush with the resin back surface 22. The fifth back surface 42B is used as a mounting surface when mounting the semiconductor device A1 on a circuit board.

The fifth end surface 43B is a surface extending along the thickness direction z and the second direction y. The fifth end surface 43B may be connected to the fifth main surface 41B and the fifth back surface 42B. The fifth end surface 43B is exposed from the second resin side surface 23B. The fifth end surface 43B may be flush with the second resin side surface 23B.

The thick portion 45B is a portion that includes at least a portion of the fifth main surface 41B and at least a portion of the fifth back surface 42B. In the present embodiments, the thick portion 45B is located on the outer side of the fourth lead 4B in the first direction x.

The thin portion 46B is a portion that includes at least a portion of the fifth main surface 41B, but does not include the fifth back surface 42B. The thin portion 46B is covered with the sealing resin 2 from the other side in the thickness direction z. In the embodiments, the thin portion 46B extends inward in the first direction x from the thick portion 45B.

The semiconductor element 1 may be conductively bonded to a portion of the fifth main surface 41B included in the thick portion 45B via a conductive bonding material 18.

As shown in FIGS. 1 to 3, the island lead 9 may be provided at a center of the semiconductor device A1 as viewed in the thickness direction z. As shown in FIGS. 6, 7, 11, 12, and 16, the island lead 9 may have an island main surface 91, an island back surface 92, and two island connectors 93. The specific shape of the island lead 9 is not limited in any way, and may be various shapes such as a rectangular shape, a polygonal shape, a circular shape, an elliptical shape, and the like as viewed in the thickness direction z. In the illustrated example, the island lead 9 has a rectangular shape. The size of the island lead 9 is not limited in any way, and in the illustrated example, may be smaller than the size of the semiconductor element 1 as viewed in the thickness direction z.

The island main surface 91 faces the same side as the resin main surface 21 in the thickness direction z. The island main surface 91 may face the semiconductor element 1. The island main surface 91 may be spaced apart from the semiconductor element 1 via the sealing resin 2. Unlike the illustrated example, the island main surface 91 may be bonded to the semiconductor element 1 by solder or the like.

The island back surface 92 faces the same side as the resin back surface 22 in the thickness direction z. The island back surface 92 is exposed from the resin back surface 22. The island back surface 92 may be flush with the resin back surface 22. The island back surface 92 is used as a mounting surface when the semiconductor device A1 is mounted on a circuit board.

The two island connectors 93 may be connected to the two fourth leads 4B. In the illustrated example, the island connector 93 extends along the first direction x. The island connector 93 may include a portion of the island main surface 91 and may not include the island back surface 92. The island connector 93 may be covered with the sealing resin 2 from the other side in the thickness direction z.

Next, the operation of the semiconductor device A1 will be described.

As shown in FIGS. 16 and 17, when the semiconductor device A1 is mounted on a circuit board Sb, a conductive bonding material Sd such as solder or the like may be attached to the first back surface 32 and the third back surface 52A. This makes it possible to reduce stress generated in the conductive bonding material Sd attached to the first back surface 32, compared to a case in which solder is attached only to the first back surface 32 and the third back surface 52A is not present. Therefore, according to the embodiments, it is possible to reduce stress generated in the conductive bonding material Sd used for mounting.

In addition, if a crack occurs in the conductive bonding material Sd attached to the first back surface 32, the presence of the conductive bonding material Sd attached to the third back surface 52A can suppress the crack from reaching the conductive bonding material Sd attached to the second back surface 42A. Since the fourth back surface 62A is located on one side of the resin back surface 22 in the thickness direction z and is covered by the sealing resin 2, the conductive bonding material Sd attached to the first back surface 32 and the conductive bonding material Sd attached to the third back surface 52A are separated from each other. This configuration is preferable for suppressing the progression of the crack.

Since the first lead 3 is connected to the third lead 5A by the first connector 6A, the first lead 3 is less likely to fall off from the sealing resin 2 than when the first lead 3 is provided as a single body. This makes it possible to improve the operational reliability of the semiconductor device A1.

Since the size W11 is smaller than the size W01, it is possible to prevent the size of the semiconductor device A1 from increasing while providing the third lead 5A. If the distance D11 is the same as the distance D01, it is possible to more reliably secure the insulation distance between the second lead 4A and the third lead 5A. Since the distance D21 is smaller than the distance D11, it is possible to prevent the size of the semiconductor device A1 from increasing while providing the first connector 6A.

Since the size L3 is smaller than the size L1 and the size L2, when the first lead 3, the first connector 6A, and the third lead 5A are viewed as an integrated member from the thickness direction z, the first connector 6A has a constricted shape. As a result, the sealing resin 2 has a shape that flows toward the first connector 6A. This is preferable for preventing the integrated member that constitutes the first lead 3, the first connector 6A, and the third lead 5A from falling off from the sealing resin 2.

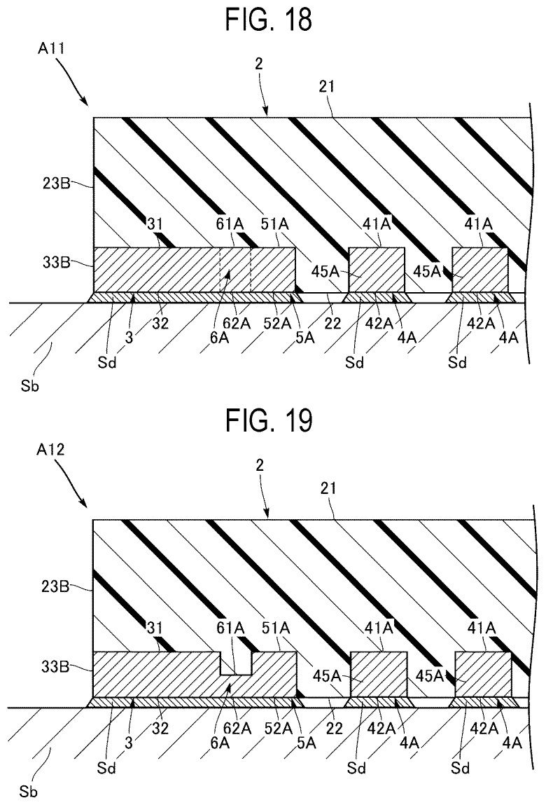

FIGS. 18 to 26 show modifications and other embodiments of the present disclosure. In these figures, elements that are the same as or similar to those in the above-described embodiments are designated by the same reference numerals as those used in the above-described embodiments. Further, the configurations of the various parts in each modification and each embodiment may be appropriately combined with each other as long as no technical contradiction occurs.

FIG. 18 shows a first modification of the semiconductor device A1. In the semiconductor device A11 of this modification, the fourth back surface 62A is exposed from the resin back surface 22. The fourth back surface 62A may be flush with the first back surface 32, the third back surface 52A, and the resin back surface 22.

This modification can reduce the stress generated in the conductive bonding material Sd used for mounting. As can be understood from this modification, the specific position of the fourth rear surface 62A in the thickness direction z is not limited in any way. In this modification, the conductive bonding material Sd can be integrally formed over the first rear surface 32, the fourth rear surface 62A, and the third rear surface 52A. Even with this configuration, since the size L3 of the first connector 6A is smaller than the size L1 and the size L2, when a crack occurs on the first rear surface 32, it is possible to suppress the crack from progressing to the third rear surface 52A.

FIG. 19 shows a second modification of the semiconductor device A1. In the semiconductor device A12 of this modification, the fourth main surface 61A is located between the first main surface 31 and the third main surface 51A and the first back surface 32 and the third back surface 52A in the thickness direction z.

This modification can reduce the stress generated in the conductive bonding material Sd used for mounting. As can be understood from this modification, the specific position of the fourth main surface 61A in the thickness direction z is not limited in any way.

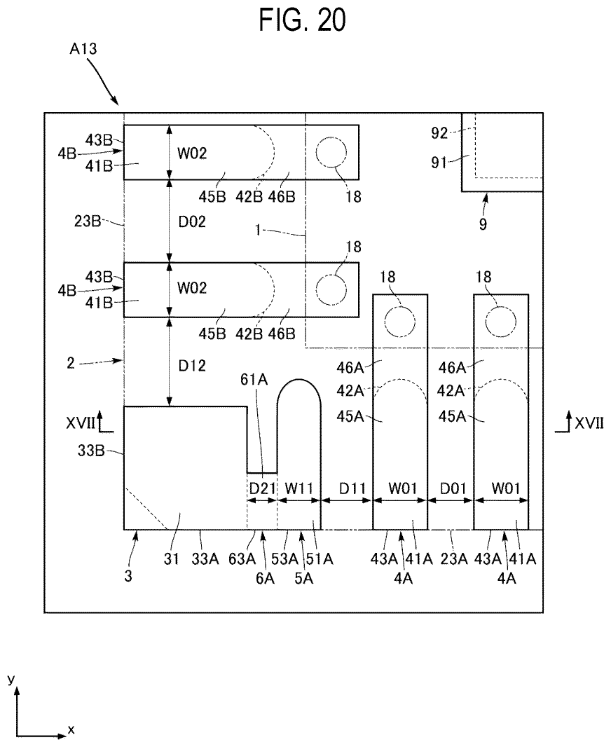

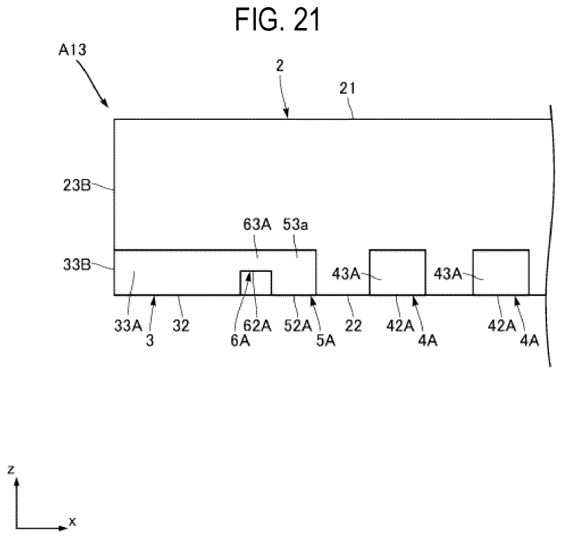

FIGS. 20 and 21 show a third modification of the semiconductor device A1. In the semiconductor device A13 of this modification, the first connector 6A may have a ninth end surface 63A.

The ninth end surface 63A is exposed from the first resin side surface 23A. The ninth end surface 63A may be flush with the first end surface 33A and the fourth end surface 53A. The size L3 may be smaller than the size L1 and the size L2.

This modification can reduce the stress generated in the conductive bonding material Sd used for mounting. As can be understood from this modification, the first connector 6A may be configured to be exposed from the first resin side surface 23A.

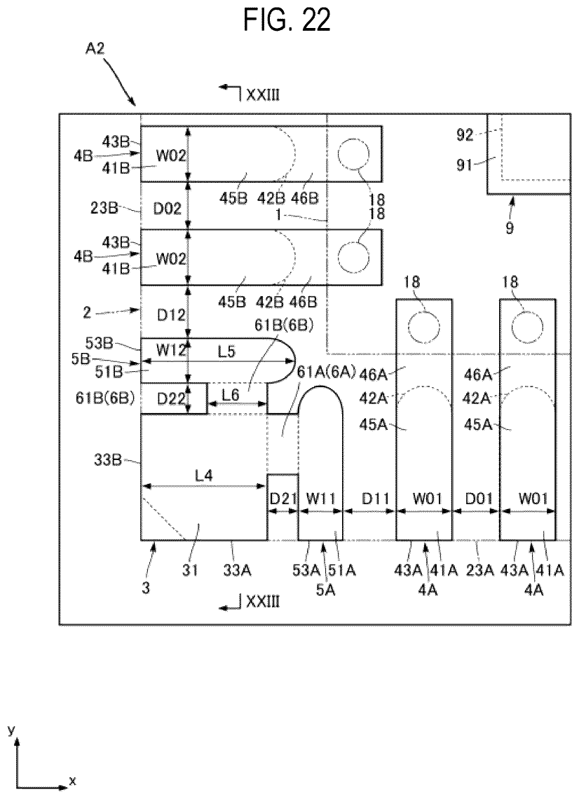

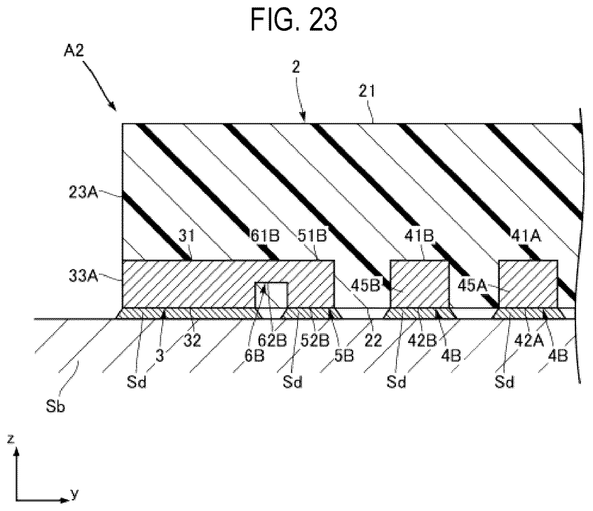

FIGS. 22 and 23 show a semiconductor device according to embodiments of the present disclosure. The semiconductor device A2 of the embodiments may include one or more fifth leads 5B and one or more second connectors 6B.

The number of the one or more fifth leads 5B is not limited in any way. In the present embodiments, the number of the one or more fifth leads 5B may be plural, for example, four. The fifth lead 5B is provided between the first lead 3 and the fourth lead 4B in the second direction y. The fifth lead 5B may have a sixth main surface 51B, a sixth back surface 52B, and a sixth end surface 53B.

The sixth main surface 51B faces the same side as the resin main surface 21 in the thickness direction z. The sixth main surface 51B may be covered with the sealing resin 2. The sixth back surface 52B faces the same other side as the resin back surface 22 in the thickness direction z. The sixth back surface 52B is exposed from the resin back surface 22. The sixth back surface 52B may be flush with the resin back surface 22. The sixth back surface 52B is used as a mounting surface when mounting the semiconductor device A2 on a circuit board.

The sixth end surface 53B is a surface extending along the thickness direction z and the second direction y. The sixth end surface 53B may be connected to the sixth main surface 51B and the sixth back surface 52B. The sixth end surface 53B is exposed from the second resin side surface 23B. The sixth end surface 53B may be flush with the second resin side surface 23B.

The number of the one or more second connectors 6B is not limited in any way. In the embodiments, the number of the one or more second connectors 6B may be plural, for example, four. The second connector 6B is provided between the first lead 3 and the fifth lead 5B in the second direction y to connect the first lead 3 and the fifth lead 5B. The second connector 6B may have a seventh main surface 61B and a seventh back surface 62B.

The seventh main surface 61B faces the same side as the resin main surface 21 in the thickness direction z. The seventh main surface 61B may be covered with the sealing resin 2. The seventh back surface 62B faces the same other side as the resin back surface 22 in the thickness direction z. The seventh back surface 62B may be located between the seventh main surface 61B and the resin back surface 22 in the thickness direction z, and may be covered with the sealing resin 2.

In the illustrated example, the second connector 6B may be spaced apart from the second resin side surface 23B in the first direction x. The second connector 6B may be covered with the sealing resin 2 from the outside in the first direction x.

The first lead 3, the fifth lead 5B and the second connector 6B may be separate from the semiconductor element 1 and may be insulated from the semiconductor element 1.

A size W12 of the fifth lead 5B in the second direction y may be smaller than a size W02 of the fourth lead 4B in the second direction y. A distance D12 between the fourth lead 4B and the fifth lead 5B in the second direction y may be the same as a distance D02 between the adjacent fourth leads 4B in the second direction y. A distance D22 between the first lead 3 and the fifth lead 5B in the second direction y may be smaller than the distance D12. The specific values of the size W02, the size W12, the distance D02, the distance D12, and the distance D22 are not limited in any way. As an example of each value, the size W02 may be 0.15 mm or more and 0.3 mm or less. The size W12 may be 0.1 mm or more and 0.3 mm or less. The distance D02 may be 0.15 mm or more and 0.3 mm or less. The distance D12 may be 0.15 mm or more and 0.6 mm or less. The distance D22 may be 0.15 mm or more and 0.6 mm or less.

A size L6 of the second connector 6B in the first direction x may be smaller than a size L5 of the fifth lead 5B in the first direction x. The size L6 may be smaller than a size L4 of the first lead 3 in the first direction x. The size L5 may be larger than the size L4. The specific values of L4, L5, and L6 are not limited in any way. As an example of each value, the size L4 may be 0.2 mm or more and 0.4 mm or less. The size L5 may be 0.4 mm or more. The size L6 may be 0.1 mm or more and 0.3 mm or less.

The positional relationship of the first main surface 31, the fifth main surface 41B, the sixth main surface 51B, and the seventh main surface 61B in the thickness direction z is not limited in any way. In the illustrated example, the first main surface 31, the fifth main surface 41B, the sixth main surface 51B, and the seventh main surface 61B may be located at the same position in the thickness direction z.

The embodiments can reduce the stress generated in the conductive bonding material Sd used for mounting. By attaching the conductive bonding material Sd to the sixth back surface 52B, another conductive bonding material Sd is positioned in both the first direction x and the second direction y with respect to the conductive bonding material Sd attached to the first back surface 32. This makes it possible to further reduce the stress generated in the conductive bonding material Sd attached to the first back surface 32. In addition, if a crack occurs in the conductive bonding material Sd attached to the first back surface 32, it is possible to prevent the crack from reaching the conductive bonding material Sd attached to the fifth back surface 42B.

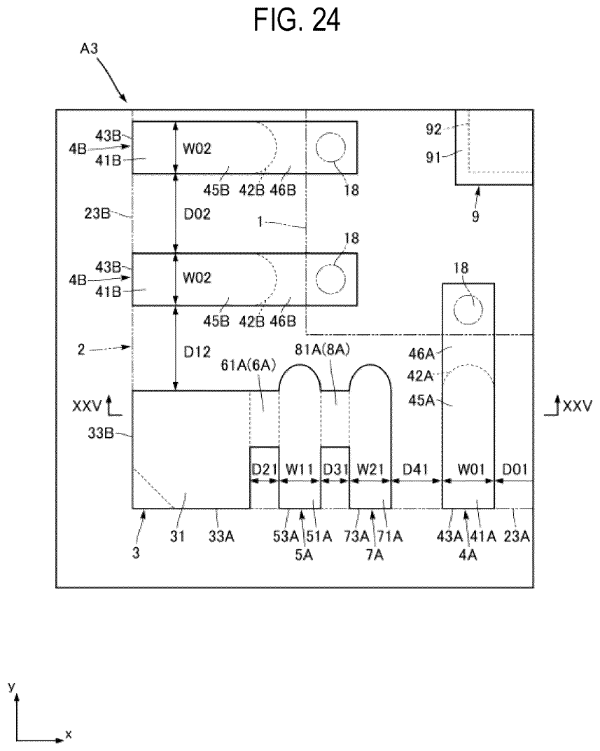

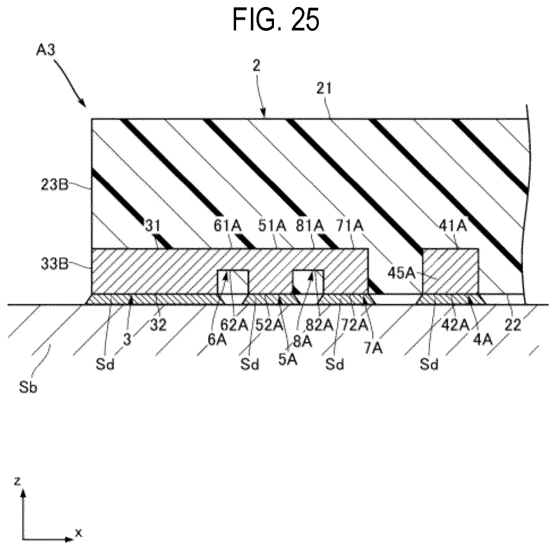

FIGS. 24 and 25 show a semiconductor device according to embodiments of the present disclosure. The semiconductor device A3 of the embodiments includes one or more sixth leads 7A and one or more third connectors 8A.

The number of the one or more sixth leads 7A is not limited in any way. In the present embodiments, the number of the one or more sixth leads 7A may be plural, for example, four. The sixth lead 7A is provided between the third lead 5A and the second lead 4A in the first direction x. The sixth lead 7A may have an eighth main surface 71A, an eighth back surface 72A, and a seventh end surface 73A.

The eighth main surface 71A faces the same side as the resin main surface 21 in the thickness direction z. The eighth main surface 71A may be covered with the sealing resin 2. The eighth back surface 72A faces the same other side as the resin back surface 22 in the thickness direction z. The eighth back surface 72A is exposed from the resin back surface 22. The eighth back surface 72A may be flush with the resin back surface 22. The eighth back surface 72A is used as a mounting surface when mounting the semiconductor device A3 on a circuit board.

The seventh end surface 73A is a surface extending along the thickness direction z and the first direction x. The seventh end surface 73A may be connected to the eighth main surface 71A and the eighth back surface 72A. The seventh end surface 73A is exposed from the first resin side surface 23A. The seventh end surface 73A may be flush with the first resin side surface 23A.

The number of the one or more third connectors 8A is not limited in any way. In the embodiments, the number of the one or more third connectors 8A may be plural, for example, four. The third connector 8A is provided between the third lead 5A and the sixth lead 7A in the first direction x to connect the third lead 5A and the sixth lead 7A. The third connector 8A may have a ninth main surface 81A and a ninth back surface 82A.

The ninth main surface 81A faces the same side as the resin main surface 21 in the thickness direction z. The ninth main surface 81A may be covered with the sealing resin 2. The ninth back surface 82A faces the same side as the resin back surface 22 in the thickness direction z. The ninth back surface 82A may be located between the ninth main surface 81A and the resin back surface 22 in the thickness direction z, and may be covered with the sealing resin 2.

In the illustrated example, the third connector 8A may be spaced apart in the second direction y from the first resin side surface 23A. The third connector 8A may be covered with the sealing resin 2 from the outside in the second direction y.

As shown in FIG. 24, a size W21 of the sixth lead 7A in the first direction x may be smaller than the size W01. A distance D41 in the first direction x between the second lead 4A and the sixth lead 7A may be the same as the distance D01. A distance D31 in the first direction x between the third lead 5A and the sixth lead 7A may be smaller than the distance D31. The distance D31 may be the same as the distance D21, for example.

A size in the second direction y of the third connector 8A may be the same as the size in the second direction y of the first connector 6A. A size in the second direction y of the sixth lead 7A may be the same as the size in the second direction y of the third lead 5A, for example.

The embodiments can reduce the stress generated in the conductive bonding material Sd used for mounting. By attaching the conductive bonding material Sd to the eighth back surface 72A, the conductive bonding material Sd attached to the third back surface 52A and the conductive bonding material Sd attached to the eighth back surface 72A are present between the conductive bonding material Sd attached to the first back surface 32 and the conductive bonding material Sd attached to the second back surface 42A. This can further reduce the stress generated in the conductive bonding material Sd attached to the first back surface 32. In addition, if a crack occurs in the conductive bonding material Sd attached to the first back surface 32, it is possible to more reliably suppress the crack from reaching the conductive bonding material Sd attached to the second back surface 42A.

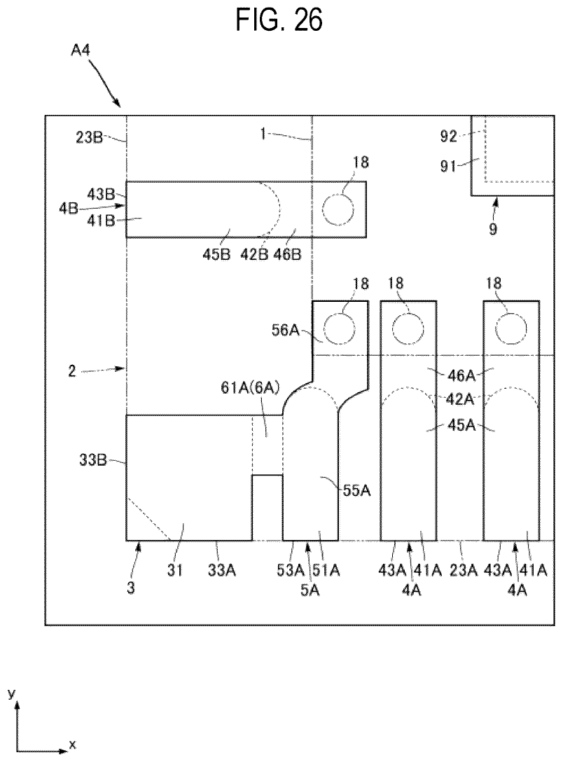

FIG. 26 shows a semiconductor device according to embodiments of the present disclosure. In the semiconductor device A4 of the embodiments, the third lead 5A includes a thick portion 55A and a thin portion 56A.

The thick portion 55A may include at least a portion of the third main surface 51A and the third back surface 52A. The thin portion 56A may include at least a portion of the third main surface 51A, but may not include the third back surface 52A. The thin portion 56A may be covered with the sealing resin 2 from the other side in the thickness direction z.

The semiconductor element 1 may be conductively bonded to a portion of the third main surface 51A included in the thin portion 56A via a conductive bonding material 18. As a result, the first lead 3, the first connector 6A, and the third lead 5A are electrically connected to the semiconductor element 1.

According to the present embodiments, it is possible to reduce the stress generated in the conductive bonding material Sd used for mounting. As can be understood from the embodiments, the first lead 3, the first connector 6A, and the third lead 5A may be electrically connected to the semiconductor element 1.

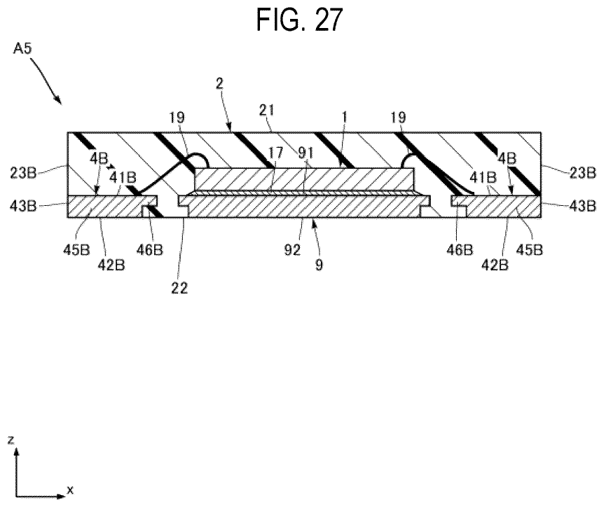

FIG. 27 shows a semiconductor device according to embodiments of the present disclosure In the semiconductor device A5 of the embodiments, the semiconductor element 1 is electrically connected to a plurality of second leads 4A and a plurality of fourth leads 4B via a plurality of connection members 19.

The connection member 19 may be, for example, a wire containing a metal such as Au (gold), Ag (silver), Cu (copper), or A1 (aluminum), or an alloy thereof. The semiconductor element 1 may be bonded to the island main surface 91 by, for example, a bonding material 17.

According to the embodiments, it is possible to reduce the stress generated in the conductive bonding material Sd used for mounting. As can be understood from the present embodiments, the semiconductor device according to the present disclosure is not limited to the configuration in which the semiconductor element 1 is flip-chip-mounted, but may include various mounting forms.

The semiconductor device according to the present disclosure is not limited to the above-described embodiments, and the specific configuration of each part of the semiconductor device according to the present disclosure may be freely designed in various ways.

### [Supplementary Note 1]

A semiconductor device (A1), comprising:
a semiconductor element (1);
a sealing resin (2) configured to cover the semiconductor element (1), the sealing resin (2) including a resin main surface (21) and a resin back surface (22) facing opposite each other in a thickness direction (z), a first resin side surface (23A) extending along a first direction (x) intersecting the thickness direction (z), and a second resin side surface (23B) extending along a second direction (y) intersecting the thickness direction (z) and the first direction (x);
a first lead (3) including a first back surface (32) exposed from the resin back surface (22), a first end surface (33A) exposed from the first resin side surface (23A), and a second end surface (33B) exposed from the second resin side surface (23B);
a second lead (4A) electrically connected to the semiconductor element (1) and including a second back surface (42A) exposed from the resin back surface (22) and a third end surface (43A) exposed from the first resin side surface (23A);
a third lead (5A) provided between the first lead (3) and the second lead (4A) in the first direction (x) and including a third back surface (52A) exposed from the resin back surface (22) and a fourth end surface (53A) exposed from the first resin side surface (23A); and a first connector (6A) configured to connect the first lead (3) and the third lead (5A).

### [Supplementary Note 2]

The semiconductor device (A1) of Supplementary Note 1, wherein the first lead (3), the third lead (5A), and the first connector (6A) are insulated from the semiconductor element (1).

### [Supplementary Note 3]

The semiconductor device (A4) of Supplementary Note 1, wherein the first lead (3), the third lead (5A), and the first connector (6A) are electrically connected to the semiconductor element (1).

### [Supplementary Note 4]

The semiconductor device (A1) of any one of Supplementary Notes 1 to 3, wherein the first lead (3) includes a first main surface (31) facing a same side as the resin main surface (21),
the second lead (4A) includes a second main surface (41A) facing the same side as the resin main surface (21),
the third lead (5A) includes a third main surface (51A) facing the same side as the resin main surface (21), and
the first connector (6A) includes a fourth main surface (61A) facing the same side as the resin main surface (21) and a fourth back surface (62A) facing a same side as the resin back surface (22).

### [Supplementary Note 5]

The semiconductor device (A1) of Supplementary Note 4, wherein the first main surface (31), the second main surface (41A), and the third main surface (51A) are located at a same position in the thickness direction (z).

### [Supplementary Note 6]

The semiconductor device (A1) of Supplementary Note 5, wherein the fourth main surface (61A) is located at the same position as the first main surface (31), the second main surface (41A), and the third main surface (51A) in the thickness direction (z).

### [Supplementary Note 7]

The semiconductor device (A12) of Supplementary Note 5, wherein the fourth main surface (61A) is located among the first main surface (31), the second main surface (41A), the third main surface (51A), and the resin back surface (22) in the thickness direction (z).

### [Supplementary Note 8]

The semiconductor device (A1) of Supplementary Note 6 or 7, wherein the fourth back surface (62A) is located between the fourth main surface (61A) and the resin back surface (22) in the thickness direction (z) and is covered with the sealing resin (2).

### [Supplementary Note 9]

The semiconductor device (A11) of Supplementary Note 6 or 7, wherein the fourth back surface (62A) is exposed from the resin back surface (22).

### [Supplementary Note 10]

The semiconductor device (A1) of any one of Supplementary Notes 1 to 9, wherein the first connector (6A) is spaced apart from the first resin side surface (23A).

### [Supplementary Note 11]

The semiconductor device (A13) of any one of Supplementary Notes 1 to 9, wherein the first connector (6A) is exposed from the first resin side surface (23A).

### [Supplementary Note 12]

The semiconductor device (A1) of any one of Supplementary Notes 1 to 11, wherein a size of the third lead (5A) in the first direction (x) is smaller than a size of the second lead (4A) in the first direction (x).

### [Supplementary Note 13]

The semiconductor device (A1) of any one of Supplementary Notes 1 to 12, wherein a distance between the first lead (3) and the third lead (5A) in the first direction (x) is smaller than a distance between the second lead (4A) and the third lead (5A) in the first direction (x).

### [Supplementary Note 14]

The semiconductor device (A2) of any one of Supplementary Notes 1 to 13, further comprising:
a fourth lead (4B) electrically connected to the semiconductor element (1) and including a fifth back surface (42B) exposed from the resin back surface (22) and a fifth end surface (43B) exposed from the second resin side surface (23B);
a fifth lead (5B) provided between the first lead (3) and the fourth lead (4B) in the second direction (y) and including a sixth back surface (52B) exposed from the resin back surface (22) and a sixth end surface (53B) exposed from the second resin side surface (23B); and a second connector (6B) configured to connect the first lead (3) and the fifth lead (5B).

### [Supplementary Note 15]

The semiconductor device (A1) of any one of Supplementary Notes 1 to 14, wherein the semiconductor element (1) is flip-chip-mounted on the second lead (4A).

### [Supplementary Note 16]

The semiconductor device (A1) of any one of Supplementary Notes 1 to 15, wherein a size of the first connector (6A) in the second direction (y) is smaller than the size of the third lead (5A) in the second direction (y).

### [Supplementary Note 17]

The semiconductor device (A1) of any one of Supplementary Notes 1 to 16, wherein the size of the first connector (6A) in the second direction (y) is smaller than a size of the first lead (3) in the second direction (y).

### [Supplementary Note 18]

The semiconductor device (A3) of any one of Supplementary Notes 1 to 17, further comprising:
a sixth lead (7A) provided between the second lead (4A) and the third lead (5A) in the first direction (x); and
a third connector (8A) configured to connect the third lead (5A) and the sixth lead (7A).

### [Supplementary Note 19]

The semiconductor device (A3) of Supplementary Note 18, wherein the sixth lead (7A) includes an eighth back surface (72A) exposed from the resin back surface (22) and a seventh end surface (73A) exposed from the first resin side surface (23A).

### [Supplementary Note 20]

The semiconductor device (A3) of Supplementary Note 19, wherein a size of the third connector (8A) in the second direction (y) is smaller than the size of the third lead (5A) and the sixth lead (7A) in the second direction (y).

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device, comprising:
a semiconductor element;
a sealing resin configured to cover the semiconductor element, the sealing resin including a resin main surface and a resin back surface facing opposite each other in a thickness direction, a first resin side surface extending along a first direction intersecting the thickness direction, and a second resin side surface extending along a second direction intersecting the thickness direction and the first direction;
a first lead including a first back surface exposed from the resin back surface, a first end surface exposed from the first resin side surface, and a second end surface exposed from the second resin side surface;
a second lead electrically connected to the semiconductor element and including a second back surface exposed from the resin back surface and a third end surface exposed from the first resin side surface;
a third lead provided between the first lead and the second lead in the first direction and including a third back surface exposed from the resin back surface and a fourth end surface exposed from the first resin side surface; and
a first connector configured to connect the first lead and the third lead.

2. The semiconductor device of claim 1, wherein the first lead, the third lead, and the first connector are insulated from the semiconductor element.

3. The semiconductor device of claim 1, wherein the first lead, the third lead, and the first connector are electrically connected to the semiconductor element.

4. The semiconductor device of claim 1, wherein the first lead includes a first main surface facing a same side as the resin main surface,
the second lead includes a second main surface facing the same side as the resin main surface,
the third lead includes a third main surface facing the same side as the resin main surface, and
the first connector includes a fourth main surface facing the same side as the resin main surface and a fourth back surface facing a same side as the resin back surface.

5. The semiconductor device of claim 4, wherein the first main surface, the second main surface, and the third main surface are located at a same position in the thickness direction.

6. The semiconductor device of claim 5, wherein the fourth main surface is located at the same position as the first main surface, the second main surface, and the third main surface in the thickness direction.

7. The semiconductor device of claim 5, wherein the fourth main surface is located among the first main surface, the second main surface, the third main surface, and the resin back surface in the thickness direction.

8. The semiconductor device of claim 6, wherein the fourth back surface is located between the fourth main surface and the resin back surface in the thickness direction and is covered with the sealing resin.

9. The semiconductor device of claim 6, wherein the fourth back surface is exposed from the resin back surface.

10. The semiconductor device of claim 1, wherein the first connector is spaced apart from the first resin side surface.

11. The semiconductor device of claim 1, wherein the first connector is exposed from the first resin side surface.

12. The semiconductor device of claim 1, wherein a size of the third lead in the first direction is smaller than a size of the second lead in the first direction.

13. The semiconductor device of claim 1, wherein a distance between the first lead and the third lead in the first direction is smaller than a distance between the second lead and the third lead in the first direction.

14. The semiconductor device of claim 1, further comprising:
a fourth lead electrically connected to the semiconductor element and including a fifth back surface exposed from the resin back surface and a fifth end surface exposed from the second resin side surface;
a fifth lead provided between the first lead and the fourth lead in the second direction and including a sixth back surface exposed from the resin back surface and a sixth end surface exposed from the second resin side surface; and
a second connector configured to connect the first lead and the fifth lead.

15. The semiconductor device of claim 1, wherein the semiconductor element is flip-chip-mounted on the second lead.
